(19) United States
(12) Patent Application Publication
(10) Pub. No.: US 2009/0236129 A1
(43) Pub. Date: Sep. 24, 2009

(54) METHODS FOR REDUCING CORROSION ON PRINTED CIRCUIT BOARDS

(75) Inventors: Randolph D. Schueller, Austin, TX (US); Thad C. McMillan, JR., Round Rock, TX (US)

Correspondence Address: ANDREA E. TRAN;PRAMUDJI WENDT & TRAN, LLP, 1800 BERING DRIVE, SUITE 540, HOUSTON, TX, 77057, US

(73) Assignee: DELL PRODUCTS L.P., Round Rock, TX (US)

(21) Appl. No.: 12/051,583

(22) Filed: Mar. 19, 2008

(51) Int. Cl. B05D 5/12; G03F 7/20; H05K 1/09

(52) U.S. Cl. 174/257; 427/97.3; 430/319

(57) ABSTRACT

A method for processing a printed circuit board (PCB) wherein the method includes providing a substrate in contact with a metal surface, contacting the metal surface with an immersion silver solution thereby producing an immersion silver layer upon the metal surface, and thereafter, providing a solder mask in contact with the metal surface and the immersion silver layer.

### BACKGROUND

1. Technical Field

The present disclosure relates generally to the field of printed circuit boards (PCBs) and, more specifically, to methods of fabricating and reducing corrosion thereof.

2. Background Information

As the value and use of information continues to increase, individuals and businesses seek additional ways to process and store information. One option available to users is an information handling system. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for such systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

A circuit board is an assembly of layers utilized to mechanically support and/or electrically couple internal components within an information handling system (IHS). Alternatives for a circuit board may include a printed circuit board (PCB), printed board, printed wiring board (PWB) and etched wiring board. The manufacture of a lead free circuit board may involve the integration of numerous elements and/or materials in a multi-step process including the introduction of a silver coating applied with an immersion plating process.

Circuit boards which incorporate a silver immersion coating may experience degradation or tarnishing which may lead to creep corrosion, particularly in environments rich in sulfur and humidity. Creep corrosion is the migration of a corrosion product along the surface of the PCB. For example, in the case of high humidity and sulfur found in the atmosphere or in heavy industrial environments, the combination of the moisture reacting with the sulfur may produce an electrolyte which may contact and further react with the metal surface (e.g. copper) generating corrosion that creeps along the surface, causing electrical failure. During the processing of a PCB, when a silver immersion layer is deposited onto the metal surface after the application of a solder mask, this may leave a small gap at the interface of the solder mask and silver layer that can expose the metal layer. The generation of corrosion product (primarily Cu₂S) can be highly accelerated due to galvanic reaction between the silver and the metal layer (e.g., copper). Conditions are favorable for a galvanic reaction since the copper is anodic with respect to the silver layer and a large electric potential separates them in the galvanic series (high driving force for corrosion). As previously mentioned, corrosion on PCBs may cause failure of some electronic components (e.g., hard drive drives) and/or reduce overall productivity in IHSs.

Improving the adhesion of a solder mask to the silver immersion layer may possibly reduce the occurrence of corrosion on PCBs. However, adhesion of the solder mask may be difficult to control, particularly in the case where the solder mask undergoes structural changes (e.g., swelling, receding) during the circuit board assembly process. To that end, the corrosion on PCBs may still occur despite the improvement of solder mask adhesive properties. Thus, a need exists for methods to reduce the development of corrosion on printed circuit boards.

### SUMMARY

The following presents a general summary of several aspects of the disclosure in order to provide a basic understanding of at least some aspects of the disclosure. This summary is not an extensive overview of the disclosure. It is not intended to identify key or critical elements of the disclosure or to delineate the scope of the claims. The following summary merely presents some concepts of the disclosure in a general form as a prelude to the more detailed description that follows.

One aspect of the disclosure provides a method for processing a printed circuit board (PCB) wherein the method includes providing a substrate in contact with a metal surface, contacting the metal surface with an immersion silver solution, thereby producing an immersion silver layer upon the metal surface, and thereafter, providing a solder mask in contact with the metal surface and the immersion silver layer.

Another aspect of the disclosure provides a method for reducing corrosion on a printed circuit board (PCB) wherein the method includes providing a substrate in contact with a metal surface, contacting the metal surface with an immersion silver solution, thereby producing an immersion silver layer upon the metal surface, and thereafter, providing a solder mask in contact with the metal surface and the immersion silver layer so as to prevent atmospheric exposure to the metal surface.

Yet another aspect of the disclosure provides a printed circuit board (PCB) including a substrate in contact with a metal surface, an immersion silver layer in contact with the metal surface and a solder mask in contact with the metal surface and the immersion silver layer, wherein the solder mask and immersion silver layer prevent atmospheric exposure to the metal surface.

### BRIEF DESCRIPTION OF THE DRAWINGS

For detailed understanding of the present disclosure, references should be made to the following detailed description of the several aspects, taken in conjunction with the accompanying drawings, in which like elements have been given like numerals and wherein:

FIG. 1 represents an illustrative schematic of an information handling system (IHS) in accord with the present disclosure;

FIG. 2 represents an illustrative schematic of a printed circuit board (PCB) in accord with the present disclosure;

FIG. 3 represents a cross sectional view of the PCB in FIG. 2; and

FIG. 4 represents an illustrative method for processing a PCB in accord with the present disclosure.

### DETAILED DESCRIPTION

Before the present methods and apparatus are described, it is to be understood that this disclosure is not limited to the particular methods and apparatus described, as such may vary. One of ordinary skill in the art should understand that the terminology used herein is for the purpose of describing possible aspects, embodiments and/or implementations only, and is not intended to limit the scope of the present disclosure which will be limited only by the appended claims.

It must also be noted that as used herein and in the appended claims, the singular forms “a,” “and,” and “the” may include plural referents unless the context clearly dictates otherwise. Thus, for example, reference to “a layer” refers to one or several layers, and reference to “a method of processing” includes reference to equivalent steps and methods known to those skilled in the art, and so forth.

For purposes of this disclosure, an embodiment of an Information Handling System (IHS) may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an IHS may be a personal computer, a storage device, or any other suitable device and may vary in size, shape, performance, functionality, and price. The IHS may include random access memory (RAM), one or more processing resources such as a central processing unit (CPU) or hardware or software control logic, ROM, and/or other types of nonvolatile memory. Additional components of the IHS may include one or more disk drives, one or more network ports for communicating with external devices as well as various input and output (I/O) devices, such as a keyboard, a mouse, and a video display. The IHS may also include one or more buses operable to transmit data communications between the various hardware components.

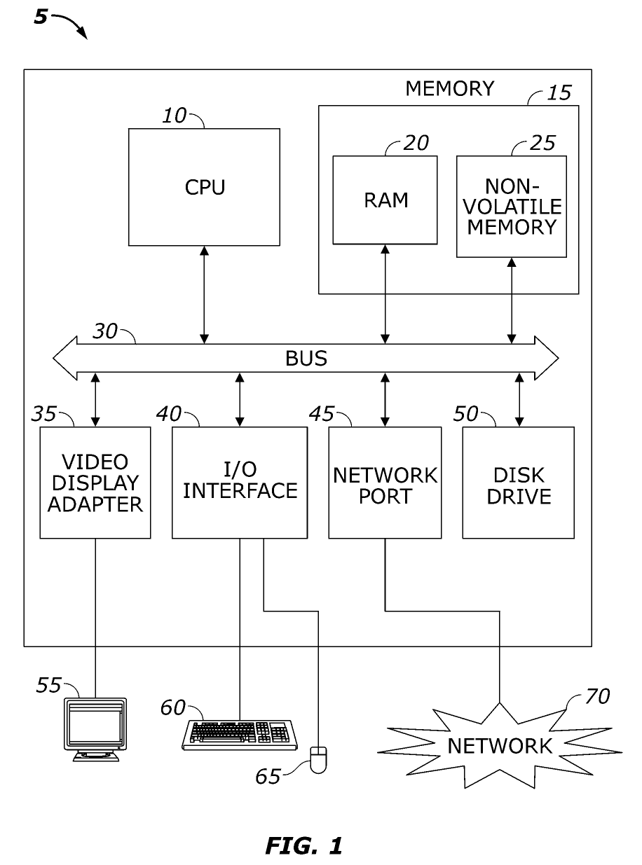

FIG. 1 illustrates one possible implementation of an IHS 5 comprising a CPU 10. It should be understood that the present disclosure has applicability to IHSs as broadly described above, and is not intended to be limited to the IHS 5 as specifically described. The CPU 10 or controller may comprise a processor, a microprocessor, minicomputer, or any other suitable device, including combinations and/or a plurality thereof, for executing programmed instructions. It is appreciated that execution of the algorithm to be described below occurs in the processor or the CPU 10. The CPU 10 may be in data communication over a local interface bus 30 with components including memory 15 and input/output interfaces 40. The memory 15, as illustrated, may include non-volatile memory 25. The non-volatile memory 25 may include, but is not limited to, flash memory 28, non-volatile random access memory (NVRAM), and electrically erasable programmable read-only memory (EEPROM). The non-volatile memory 25 may contain a firmware program (not shown) which may contain programming and/or executable instructions required to control a keyboard 60, mouse 65, video display 55 and/or other input/output devices not shown here. This type of firmware may be known as a basic input/output system (BIOS). The memory may also comprise random access memory (RAM) 20. The operating system and application programs (e.g., graphical user interfaces) may be loaded into the RAM 20 for execution.

The IHS 5 may be implemented with a network port 45 to permit communication over a network 70 such as a local area network (LAN) or a wide area network (WAN), such as the Internet. As understood by those skilled in the art, IHS 5 implementations may also include an assortment of ports and interfaces for different peripherals and components, such as video display adapters 35, disk drives port 50, and input/output interfaces 40 (e.g., keyboard 60, mouse 65).

Included within the hardware components of an IHS may be a circuit board or printed circuit board (PCB) indicated generally at 200 in FIG. 1. The circuit board 200 may comprise a substrate 205 onto which a conductive pattern of traces 210 is disposed. As a non-conductive foundation, the substrate 205 may consist of any suitable non-conductive or insulating material, examples of which may include composites, laminate materials, fiberglass, epoxy glass, paper, ceramic, plastic or the like. The entire substrate 205 or only its surface to which the conductive pattern is disposed may be formed of an insulating material. Generally, a circuit board 200 may comprise at least one layer of conductive pattern 210 separated and supported by at least one layer of substrate 205.

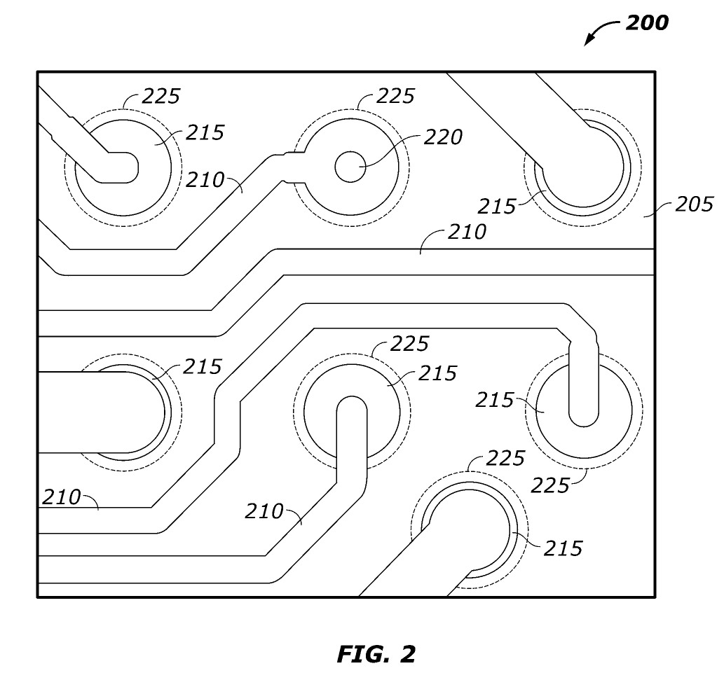

Continuing with FIG. 2, the conductive pattern disposed on the circuit board 200 may comprise a trace 210 which may comprise a number of terminations at pads 215 or vias 220, collectively referred to herein as “terminals.” Traces 210, also known in the art as tracks, circuit lines or wires, interconnect electrical components, (e.g., resistors, diodes, transistors) which in the process of manufacturing an IHS will be placed on one or both surfaces of the circuit board 200. The traces 210 may be etched from a metal surface such as copper and its alloys, aluminum and its alloys or other suitable metallic conductors, onto the substrate 205. The pads 215 may be areas of the circuit board 200 for connection and attachment of electronic components whereas vias 220 are holes or apertures in the circuit board 200 for the purpose of layer-to-layer interconnection. Projection lines 225 are not part of the circuit board 200 but are provided in FIG. 2 to illustrate positioning of solder mask openings that will be formed in the application of a solder mask (e.g., coating or inert coating) layer.

A printed circuit board (PCB) as shown generally in FIG. 2 may comprise an assembly of the layers previously described. However, for the purpose of this disclosure, it is also understood that a circuit board assembly exists at any stage of a multi-step assembly process to produce a PCB provided that at least a substrate layer is present.

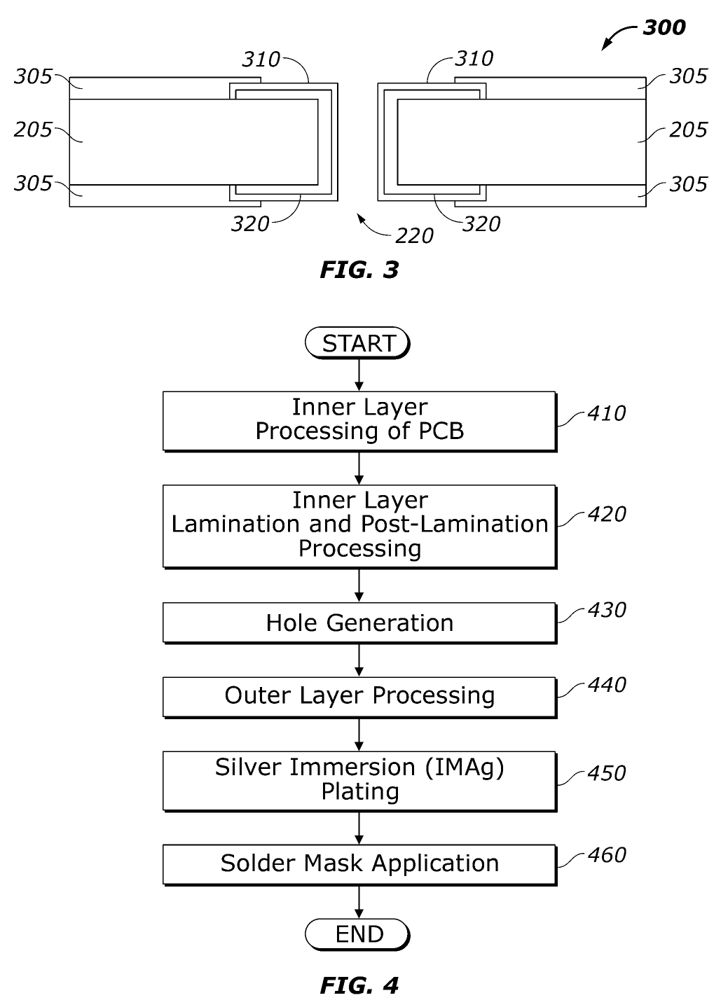

Now referring to FIG. 3, a cross sectional view of the PCB 200 is indicated generally at 300. The centermost substrate 205 layer comprising epoxy glass or other suitable material is shown in contact with at least one solder mask 305 layer, metal surface 320 and immersion silver (IMAg) layer 310. As mentioned previously, the metal surface 320 may consist of copper and its alloys, aluminum and its alloys, other suitable metallic conductors or a combination thereof. A via 220 or hole in the PCB is shown separating portions of the PCB 200 layers. The solder mask 305 or solder resist may comprise a layer of polymer to provide a protective coating for the traces 210. In contact with the solder mask 305 is shown the IMAg layer 310 formed from an immersion silver solution which may comprise silver in composition with other materials such as organic components. As described in detail below, during the process of fabricating the PCB, an IMAg layer 310 may be formed by the introduction of an immersion silver solution or thin deposits of silver directly to the surface of the metal surface 320 prior to the application of the solder mask 305. As seen in FIG. 3, one end of the solder mask 305 may be layered above both the IMAg 310 and metal surface 320. Atmospheric exposure or environmental access to the metal surface 320, therefore, may be eliminated and thus preventing galvanic corrosion at the surface of the metal surface 320.

Now referring to FIG. 4, an illustrative method for processing a PCB is provided. The present disclosure contemplates various methods comprising all or less than all of the steps discussed below including any number of repeats of any of the steps. In step 410, inner layer processing of the PCB occurs first providing a substrate in contact with a metal surface (e.g., copper) on one or both sides. At this stage, a circuit board assembly may comprise components such as the substrate in contact with the metal surface along with any subsequently added materials or layers to the metal surface and/or substrate.

A light sensitive film (e.g., polymer, photoresist coat) may then be applied (e.g., laminated, sprayed) and in some cases, by heat and pressure, to the top and/or bottom surfaces of the metal surface. Examples of light sensitive films may include dry film resist and other conventional films. The circuit board assembly may then be exposed to light (e.g., ultraviolet (UV)). Upon exposure to UV light, certain areas of the light sensitive film may allow the passage of light and as a result, may polymerize or harden, thus creating an image of a conductive pattern. The circuit board assembly including light sensitive film may then be immersed in an acid solution (e.g., H₂SO₄, H₃PO₄) to remove areas of light sensitive film not polymerized from the exposure to UV light. Subsequently, an etching process may occur in which copper is chemically removed by the acid from areas not covered by light sensitive film to define a conductive pattern. The light sensitive film may then be chemically removed leaving the copper conductive pattern exposed. The copper can then be chemically treated with any suitable coating, such as one comprising oxide, to improve properties such as adhesion.

Continuing with FIG. 4, in step 420, the circuit board assembly may undergo an inner layer lamination and post-lamination process. The inner layer lamination may occur as single or multi-layer lamination with elements including metal sheets (e.g., copper foil) and resin (e.g., expoxy, prepreg) bonded with the substrate and layers under heat and pressure, typically in a vacuum. Subsequently, in step 430, holes may be generated within the circuit board assembly through drilling or other conventional means for generating holes in PCBs. In one possible implementation, an electroless copper process may then occur wherein an additional metal surface (e.g., copper) is plated to cover all exposed surfaces includes all sides of the holes.

The outer layer of the circuit board assembly may now be processed in step 440. Similar to the above described internal lamination process, light sensitive film may be laminated over the exposed surfaces of the circuit board assembly including the top, bottom and sides of the holes. An external imaging process may then occur whereby the circuit board assembly is first exposed to ultraviolet (UV) light. Clear areas not covered by copper allow the UV light to pass through and harden (e.g., polymerize) the sensitive film, thus creating an image of the circuit pattern. The circuit board assembly may then be developed, leaving behind an exposed image or negative image of the PCB pattern.

A first electro-plating process may then occur in which additional copper is added to exposed surfaces of the circuit board assembly to increase copper thickness on outer layers. Next, a second electro-plating process may occur in which tin or another comparable metal added to the entire board over the exposed copper surface including the top and bottom of the circuit board assembly and all sides of the holes. Tin or tin lead is plated on the entire board where the copper traces will remain. The light sensitive film may then be removed to leave behind tin plating and copper surface. During another possible etching process, copper may be removed from areas not exposed by the tin, followed by the removal of the tin plating. The removal of the tin plating may reduce the copper thickness of the outer layers.

In step 450, silver immersion (IMAg) plating occurs with the introduction of an organic silver solution to the circuit board assembly. Immersion plating generally refers to a process which results from a replacement reaction whereby the surface being plated dissolves into solution while the material or metal being plated deposits from the plating solution onto the surface being plated. In one possible method of plating, a thin layer of silver (Ag) is deposited to any area of exposed metal surface by the replacement reaction in which the Ag displaces the copper on the pads. The Ag may be deposited by introducing the circuit board assembly into a silver solution bath. The thickness of the layer of Ag deposited on the metal surface may be from about 0.125 μm to 0.375 μm. One skilled in the art may appreciate that prior to IMAg, the copper surface may undergo suitable preparatory steps such as cleaning, microetching of the copper, rinsing and the like. It is generally known that immersion silver may provide enhanced solderabillity useful in the fabricating of PCBs. Particularly, Ag may provide a flat solderable surface for the steps to be described below.

Continuing with FIG. 4, step 460 occurs as a layer of solder mask is applied to the circuit board assembly following the silver immersion plating. The solder mask may be applied (e.g., laminated, screened) in various forms, examples of which include a liquid mask, liquid film or dry film, then left to dry by any suitable drying means. The circuit board assembly or PCB can then be subjected to processes including, but not limited to, imaging, developing and curing, thereby resulting in exposed copper surfaces.

Those skilled in art will appreciate that the disclosure contemplates other convention methods of processing a circuit board assembly or PCB in which silver immersion plating occurs prior to the solder mask application now known or to be developed in the future. As mentioned herein, plating the silver prior to application of the solder mask, particularly to reduce the metal surface's exposure to the atmosphere and environmental elements, (e.g., sulfur, humidity) may reduce the occurrence of corrosion on the metal surface.

Although the present disclosure has been described with reference to particular examples, embodiments and/or implementations, those skilled in the art will recognize that modifications and variations may be made without departing from the spirit and scope of the claimed subject matter. Such changes in form and detail, including use of equivalent functional and/or structural substitutes for elements described herein, fall within the scope of the appended claims and are intended to be covered by this disclosure.

What is claimed is:

1. A method for processing a printed circuit board (PCB), the method comprising:
providing a substrate in contact with a metal surface;
contacting the metal surface with an immersion silver solution thereby producing an immersion silver layer upon the metal surface; and thereafter
providing a solder mask in contact with the metal surface and the immersion silver layer.

2. The method of claim 1, wherein the metal surface is selected from the group consisting of copper, copper alloy, aluminum, aluminum alloy and a combination thereof.

3. The method of claim 1, wherein the substrate is selected from the group consisting of a composite, a laminate, fiberglass, epoxy glass, ceramic, plastic and a combination thereof.

4. The method of claim 1, wherein the solder mask and the immersion silver layer prevent atmospheric exposure to the metal surface.

5. The method of claim 1, wherein the step of contacting the metal surface with an immersion silver solution comprises introducing a silver deposit to the metal surface or immersing the substrate and metal surface in a silver solution.

6. The method of claim 1 further comprising the step of applying a light sensitive film to at least one side of the metal surface.

7. The method of claim 6, wherein the light sensitive film is selected from a polymer, a photoresist and a combination thereof.

8. The method of claim 6 further comprising exposing the light sensitive film to ultraviolet light to polymerize the film.

9. A method for reducing corrosion on a printed circuit board (PCB), the method comprising:
providing a substrate in contact with a metal surface;
contacting the metal surface with an immersion silver solution thereby producing an immersion silver layer upon the metal surface; and thereafter
providing a solder mask in contact with the metal surface and the immersion silver layer so as to prevent atmospheric exposure to the metal surface.

10. The method of claim 9, wherein the metal surface is selected from the group consisting of copper, copper alloy, aluminum, aluminum alloy and a combination thereof.

11. The method of claim 9, wherein the substrate is selected from the group consisting of a composite, a laminate, fiberglass, epoxy glass, ceramic, plastic and a combination thereof.

12. The method of claim 9, wherein the step of contacting the metal surface with an immersion silver solution comprises introducing a silver deposit to the metal surface or immersing the substrate and metal surface in a silver solution.

13. The method of claim 9 further comprising the step of applying a light sensitive film to at least one side of the metal surface.

14. The method of claim 13, wherein the light sensitive film is selected from a polymer, a photoresist and a combination thereof.

15. The method of claim 13 further comprising exposing the light sensitive film to ultraviolet light to polymerize the film.

16. A printed circuit board (PCB) comprising:
a substrate in contact with a metal surface;
an immersion silver layer in contact with the metal surface; and
a solder mask in contact with the metal surface and the immersion silver layer, wherein the solder mask and immersion silver layer prevent atmospheric exposure to the metal surface.

17. The printed circuit board (PCB) of claim 16, wherein the PCB is a multi-layer assembly.

18. The printed circuit board (PCB) of claim 16, wherein the metal surface is selected from the group consisting of copper, copper alloy, aluminum, aluminum alloy and a combination thereof.

19. The printed circuit board (PCB) of claim 16, wherein the substrate is selected from the group consisting of a composite, a laminate, fiberglass, epoxy glass, ceramic, plastic and a combination thereof.

20. The printed circuit board (PCB) of claim 16, wherein the immersion silver layer is formed from the depositing of silver to the metal surface or immersion of the substrate and metal surface in a silver solution.
